(19) United States
(12) Patent Application Publication
(10) Pub. No.: US 2025/0239997 A1
(43) Pub. Date: Jul. 24, 2025

(54) ACOUSTIC IMPEDANCE INVERTER

(71) Applicant: Qorvo US, Inc., Greensboro, NC (US)

(72) Inventor: Nadim Khlat, Cugnaux (FR)

(21) Appl. No.: 18/971,773

(22) Filed: Dec. 6, 2024

Related U.S. Application Data
(60) Provisional application No. 63/622,613, filed on Jan. 19, 2024.
(60) Provisional application No. 63/573,047, filed on Apr. 2, 2024.

(51) Int. Cl. H03H 11/40; H03H 9/13; H03H 9/54

(52) U.S. Cl. CPC H03H 11/40; H03H 9/132; H03H 9/542

(57) ABSTRACT

An acoustic impedance inverter is provided. In an embodiment, the acoustic impedance inverter can be coupled to an acoustic filter to provide needed impedance inversion at, for example, a series resonance frequency of the acoustic filter. In contrast to a conventional impedance inverter, which typically involves negatively coupled transformers, the acoustic impedance inverter utilizes a pair of acoustically coupled interdigital transducers (IDTs) to provide the needed impedance inversion at a tunable frequency. As a result, the acoustic impedance inverter can be implemented with a lower insertion loss and on a smaller footprint compared to the conventional impedance inventor.

### RELATED APPLICATIONS

This application claims the benefit of U.S. provisional patent application Ser. No. 63/622,613, filed on Jan. 19, 2024, and U.S. provisional patent application Ser. No. 63/573,047, filed on Apr. 2, 2024, the disclosures of which are hereby incorporated herein by reference in their entireties.

### FIELD OF THE DISCLOSURE

The technology of the disclosure relates generally to an impedance inverter.

### BACKGROUND

Wireless devices have become increasingly common in current society. The prevalence of these wireless devices is driven in part by the many functions that are now enabled on such devices for supporting a variety of applications. In this regard, a wireless device may employ a variety of circuits and/or components (e.g., filters, transceivers, antennas, and so on) to support different numbers and/or types of applications. Accordingly, the wireless device may include a number of switches to enable dynamic and flexible couplings between the variety of circuits and/or components.

Acoustic resonators, such as surface acoustic wave (SAW) resonators and bulk acoustic wave (BAW) resonators, are used in many high-frequency communication applications. In particular, SAW resonators are often employed in filter networks that operate at frequencies up to 1.8 GHZ, and BAW resonators are often employed in filter networks that operate at frequencies above 1.5 GHZ. Such filters need to have flat passbands, steep filter skirts and squared shoulders at the upper and lower ends of the passbands, and provide excellent rejection outside of the passbands. SAW and BAW-based filters also have relatively low insertion loss, tend to decrease in size as the frequency of operation increases, and are relatively stable over wide temperature ranges.

As such, SAW and BAW-based filters are the filters of choice for Fifth Generation (5G) and 5G new radio (5G-NR) wireless devices. While these demands keep raising the complexity of wireless devices, there is a constant need to reduce footprint size and improve performance of acoustic filters.

### SUMMARY

Aspects disclosed in the detailed description include an acoustic impedance inverter. In an embodiment, the acoustic impedance inverter can be coupled to an acoustic filter to provide a needed impedance inversion at, for example, a series resonance frequency of the acoustic filter. In contrast to a conventional impedance inverter, which typically involves negatively coupled transformers, the acoustic impedance inverter utilizes a pair of acoustically coupled interdigital transducers (IDTs) to provide the needed impedance inversion at a tunable frequency. As a result, the acoustic impedance inverter can be implemented with a lower insertion loss and on a smaller footprint compared to the conventional impedance inventor.

In one aspect, an acoustic impedance inverter is provided. The acoustic impedance inverter includes a piezo-on-insulator (POI) layer. The POI layer is provided on a substrate. The acoustic impedance inverter also includes a pair of reflectors. The pair of reflectors are provided on the POI layer. The acoustic impedance inverter also includes a pair of IDTs. The pair of IDTs are provided on the POI layer in between the pair of reflectors. The pair of IDTs are acoustically coupled to provide an impedance inversion and pass a radio frequency (RF) signal at a selected frequency.

In another aspect, an acoustic filter circuit is provided. The acoustic filter circuit includes an acoustic impedance inverter. The acoustic impedance inverter includes a POI layer. The POI layer is provided on a substrate. The acoustic impedance inverter also includes a pair of reflectors. The pair of reflectors is provided on the POI layer. The acoustic impedance inverter also includes a pair of IDTs. The pair of IDTs is provided on the POI layer in between the pair of reflectors. The pair of IDTs is acoustically coupled to provide an impedance inversion and pass an RF signal at a selected frequency. The acoustic filter circuit also includes an acoustic filter. The acoustic filter is coupled to the acoustic impedance inverter. The acoustic filter is configured to pass the RF signal to a load circuit at the selected frequency. The acoustic filter is also configured to block the RF signal from the load circuit outside the selected frequency.

In another aspect, a wireless device is provided. The wireless device includes at least one acoustic filter circuit. The at least one acoustic filter circuit includes an acoustic impedance inverter. The acoustic impedance inverter includes a POI layer. The POI layer is provided on a substrate. The acoustic impedance inverter also includes a pair of reflectors. The pair of reflectors is provided on the POI layer. The acoustic impedance inverter also includes a pair of IDTs. The pair of IDTs is provided on the POI layer in between the pair of reflectors. The pair of IDTs is acoustically coupled to provide an impedance inversion and pass an RF signal at a selected frequency. The at least one acoustic filter circuit also includes an acoustic filter. The acoustic filter is coupled to the acoustic impedance inverter. The acoustic filter is configured to pass the RF signal to a load circuit at the selected frequency. The acoustic filter is also configured to block the RF signal from the load circuit outside the selected frequency.

In another aspect, a method for implementing an acoustic impedance inverter is provided. The method includes providing a POI layer on a substrate. The method also includes providing a pair of reflectors on the POI layer. The method also includes providing a pair of IDTs on the POI layer in between the pair of reflectors. The method also includes acoustically coupling the pair of IDTs to provide an impedance inversion and pass an RF signal at a selected frequency.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure and, together with the description, serve to explain the principles of the disclosure.

FIGS. 1A and 1B are schematic diagrams illustrating a conventional impedance invertor;

FIGS. 2A and 2B are schematic diagrams of an exemplary acoustic impedance inverter configured according to an embodiment of the present disclosure;

FIGS. 3A and 3B are schematic diagrams of an exemplary tunable acoustic impedance inverter configured according to another embodiment of the present disclosure;

FIG. 4 is a schematic diagram of exemplary acoustic filter circuit wherein the acoustic impedance inverter of FIG. 2A and the tunable acoustic impedance inverter of FIG. 3A can be provided;

FIG. 5 is a schematic diagram of an exemplary communication wherein the acoustic filter circuit of FIG. 4 can be provided; and

FIG. 6 is a flowchart of an exemplary process for implementing the acoustic impedance inverter of FIG. 2A and/or the tunable acoustic impedance inverter of FIG. 3A.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include an acoustic impedance inverter. In an embodiment, the acoustic impedance inverter can be coupled to an acoustic filter to provide needed impedance inversion at, for example, a series resonance frequency of the acoustic filter. In contrast to a conventional impedance inverter, which typically involves negatively coupled transformers, the acoustic impedance inverter utilizes a pair of acoustically coupled interdigital transducers (IDTs) to provide the needed impedance inversion at a tunable frequency. As a result, the acoustic impedance inverter can be implemented with a lower insertion loss and on a smaller footprint compared to the conventional impedance inventor.

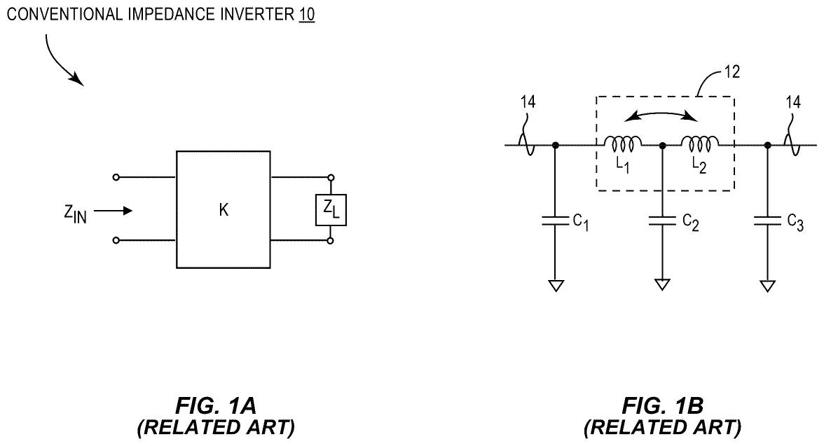

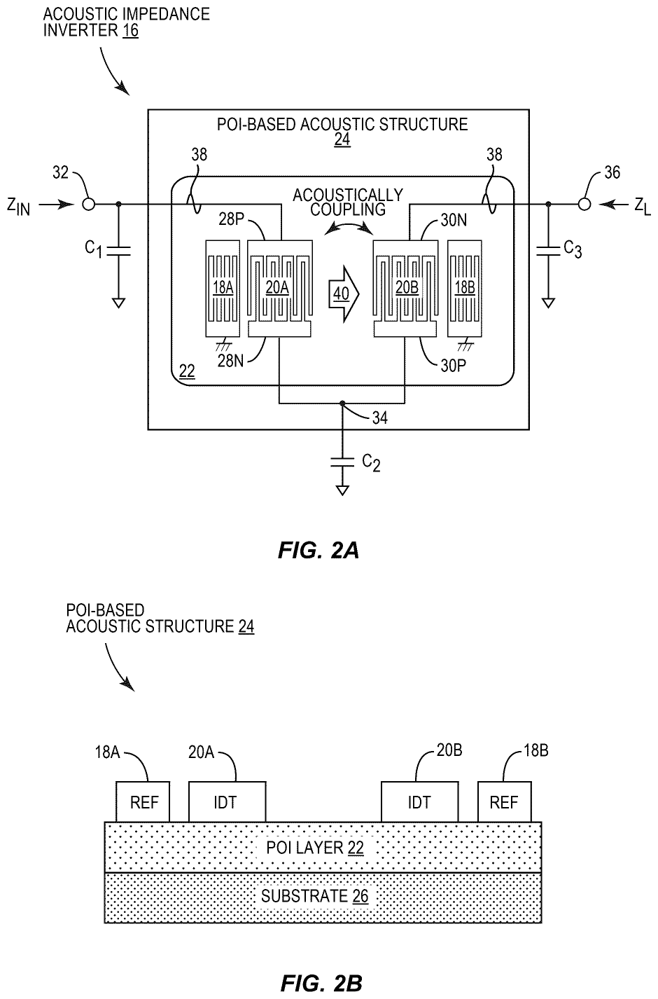

Before discussing the acoustic impedance inverter of the present disclosure, starting at FIG. 2A, a brief discussion of a conventional impedance inverter is first provided with reference to FIGS. 1A and 1B to help understand the technical problem to be solved herein.

FIG. 1A is a schematic diagram of a conventional impedance invertor 10. As shown in FIG. 1A, the conventional impedance inverter 10 can be a two-port network that relates an impedance Z_{IN} with a load impedance Z_{L} in accordance with equation (Eq. 1).

$${Z}_{IN} = {K}^{2} / {Z}_{L} \qquad ( Eq . 1 )$$

In the equation (Eq. 1), K represents a characteristic impedance (in ohms) of the conventional impedance inverter 10. Accordingly, the conventional impedance inverter 10 can also be referred to as a K-inverter. As can be seen from equation (Eq. 1), the conventional impedance inverter 10 both inverts and scales the load impedance Z_{L}.

FIG. 1B is a schematic diagram illustrating an exemplary implementation of the conventional impedance inverter 10. Herein, the conventional impedance inverter 10 includes a transformer 12, which includes a pair of negatively coupled inductors L₁, L₂. The conventional impedance inverter 10 also includes three shunt capacitors C₁, C₂, C₃ that are coupled to the transformer 12 as illustrated.

One of the issues with the conventional impedance inverter 10 is that the transformer 12 can cause an undesired insertion loss when an RF signal 14 passes through the conventional impedance inverter 10. Moreover, the conventional impedance inverter 10 may need a larger footprint to host the transformer 12. As such, it is desirable to reduce both the undesired insertion loss and the footprint in the conventional impedance inverter 10.

FIG. 2A is a schematic diagram providing an exemplary top-down view of an acoustic impedance inverter 16 configured according to an embodiment of the present disclosure. The acoustic impedance inverter 16 includes a pair of reflectors 18A, 18B and a pair of interdigital transducers (IDTs) 20A, 20B. The reflectors 18A, 18B and the IDTs 20A, 20B are all provided on a piezo-on-insulator (POI) layer 22. Herein, the IDTs 20A, 20B are provided in between the reflectors 18A, 18B. In an embodiment, the reflectors 18A, 18B, the IDTs 20A, 20B, and the POI layer 22 collectively form a POI-based acoustic structure 24.

FIG. 2B is a schematic diagram providing an exemplary sideview of the POI-based acoustic structure 24. Common elements between FIGS. 2A and 2B are shown therein with common element numbers and will not be re-described herein. As shown herein, the POI layer 22 is stacked on a substrate 26. The reflectors 18A, 18B and the IDTs 20A, 20B are provided on the POI layer 22.

With reference back to FIG. 2A, the IDT 20A includes a respective positive terminal 28P and a respective negative terminal 28N, and the IDT 20B includes a respective positive terminal 30P and a respective negative terminal 30N. Herein, the positive terminal 28P of the IDT 20A is coupled to an input port 32, whereas the negative terminal 28N is coupled to a common port 34. The positive terminal 30P of the IDT 20B, on the other hand, is coupled to the common port 34, whereas the negative terminal 30N is coupled to an output port 36. Like in the conventional impedance inverter 10, three capacitors C₁, C₂, C₃ are coupled to the input port 32, the common port 34, and the output port 36, respectively.

When an RF signal 38 is received via the input port 32, the IDT 20A converts the RF signal 38 into an acoustic wave 40. The IDT 20B, on the other hand, converts the acoustic wave 40 back to the RF signal 38 and provides the RF signal 38 to the output port 36. When the acoustic wave 40 propagates along the POI layer 22, the IDTs 20A, 20B become acoustically coupled to provide the impedance inversion in a selected frequency in accordance with the equation (Eq. 1). Since each of the IDTs 20A, 20B has a higher Q than the inductors L₁, L₂ in the conventional impedance inverter 10, the POI-based acoustic structure 24 can thus produce a lower insertion loss than the transformer 12. Moreover, since the IDTs 20A, 20B are much smaller than the inductors L₁, L₂, the POI-based acoustic structure 24 will occupy a smaller footprint than the transformer 12. In this regard, it is possible to solve the technical problems in the conventional impedance inverter 10 by replacing the transformer 12 with the POI-based acoustic structure 24.

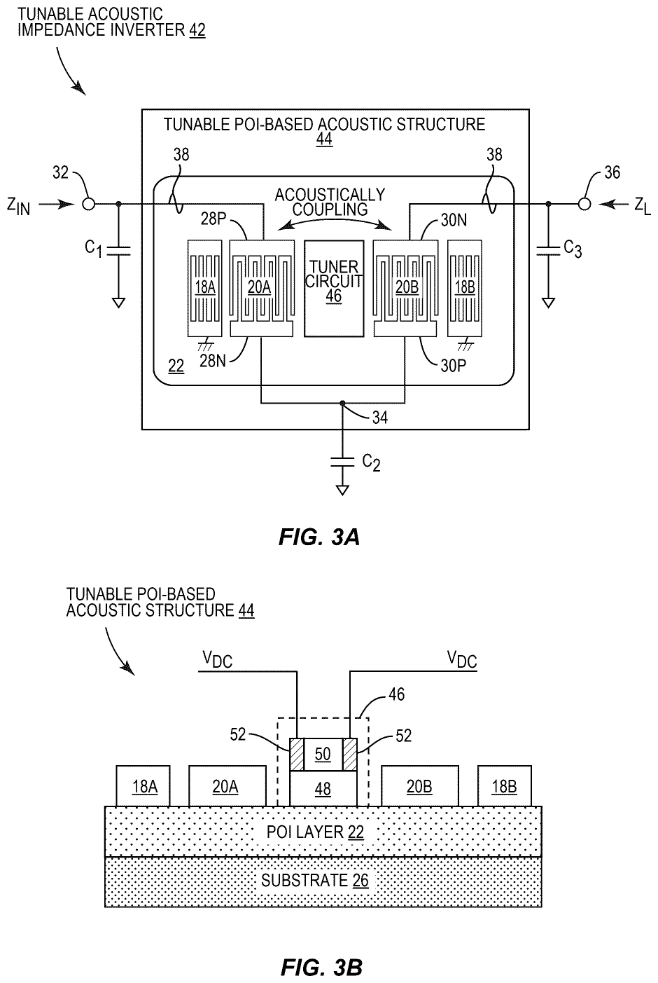

In an embodiment, the POI-based acoustic structure 24 can be tuned to provide the impedance inversion at different frequencies. In this regard, FIG. 3A is a schematic diagram of an exemplary tunable acoustic impedance inverter 42 configured according to an embodiment of the present disclosure. Common elements between FIGS. 2A and 3A are shown therein with common element numbers and will not be re-described herein.

Herein, the POI-based acoustic structure 24 is replaced by a tunable POI-based acoustic structure 44, which further includes a tuner circuit 46. FIG. 3B is a schematic diagram providing an exemplary sideview of the tunable POI-based acoustic structure 44. Common elements between FIGS. 3A and 3B are shown therein with common element numbers and will not be re-described herein.

In an embodiment, the tuner circuit 46 includes a silicon dioxide (SiO₂) layer 48, a silicon (Si) layer 50, and a pair of electrodes 52. The SiO₂ layer 48 is provided on the POI layer 22, the Si layer 50 is provided on the SiO₂ layer 48. The electrodes 52 are provided on the SiO₂ layer 48 and on each side of the Si layer 50 to form a pair of lateral sides of the Si layer 50. The tuner circuit 46 can be tuned to change the selected frequency when a direct-current (DC) voltage V_{DC} is provided to each of the electrodes 52.

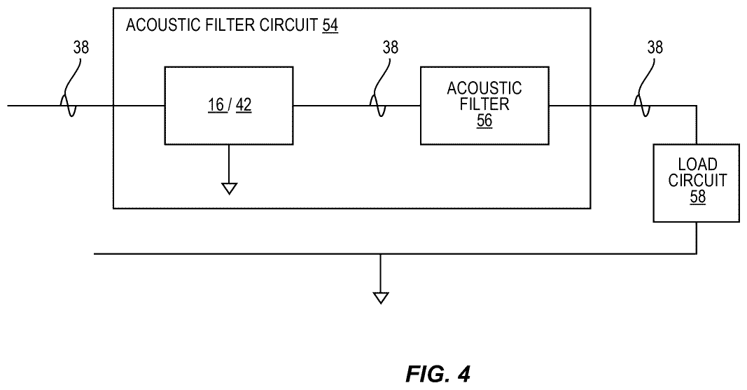

FIG. 4 is a schematic diagram of an exemplary acoustic filter circuit 54 wherein the acoustic impedance inverter 16 of FIG. 2A and/or the tunable acoustic impedance inverter 42 of FIG. 3A can be provided. Common elements between FIGS. 2A, 3A, and 4 are shown therein with common element numbers and will not be re-described herein.

Herein, the acoustic impedance inverter 16 of FIG. 2A and the tunable acoustic impedance inverter 42 of FIG. 3A can each be coupled to an acoustic filter 56 (e.g., an acoustic ladder network). In an embodiment, the acoustic filter 56 is configured to pass the RF signal 38 to a load circuit 58 in the selected frequency of the acoustic impedance inverter 16 or the tunable acoustic impedance inverter 42. The acoustic filter 56 is also configured to block the RF signal 38 from the load circuit 58 outside the selected frequency.

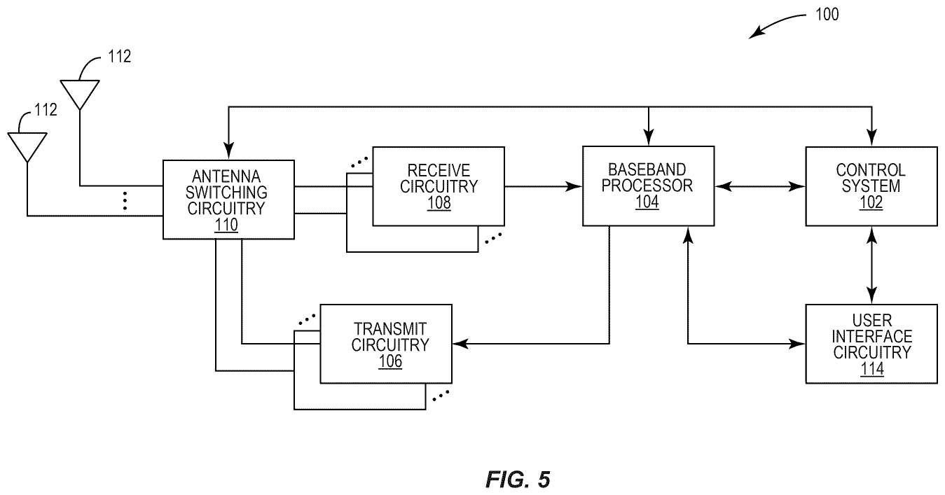

The acoustic filter circuit 54 of FIG. 4 can be provided in a communication device to support the embodiments described above. In this regard, FIG. 5 is a schematic diagram of an exemplary communication device 100 wherein the acoustic filter circuit 54 of FIG. 4 can be provided.

Herein, the communication device 100 can be any type of communication device, such as mobile terminal, smart watch, tablet, computer, navigation device, access point, base station (e.g., eNB, gNB, etc.), and like wireless communication devices that support wireless communications, such as cellular, wireless local area network (WLAN), Bluetooth, Ultra-wideband (UWB), and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

In a non-limiting example, the acoustic filter circuit 54 can be provided in the transmit circuitry 106, the receive circuitry 108, and/or the antenna switching circuitry 110.

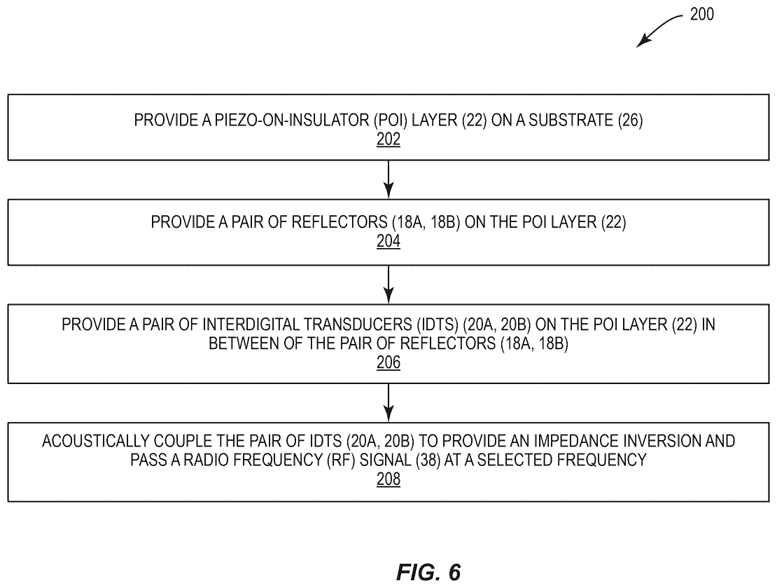

In an embodiment, it is possible to implement the acoustic impedance inverter 16 of FIG. 2A and the tunable acoustic impedance inverter 42 of FIG. 3A in accordance with a process. In this regard, FIG. 6 is a flowchart of an exemplary process 200 for implementing the acoustic impedance inverter 16 of FIG. 2A and/or the tunable acoustic impedance inverter 42 of FIG. 3A.

Herein, the process 200 includes providing the POI layer 22 on the substrate 26 (step 202). The process 200 also includes providing the pair of reflectors 18A, 18B on the POI layer 22 (step 204). The process 200 also includes providing the pair of IDTs 20A, 20B on the POI layer 22 in between the reflectors 18A, 18B (step 206). The process 200 also includes acoustically coupling the IDTs 20A, 20B to provide the impedance inversion and pass the RF signal 38 at a selected frequency (step 208).

Those skilled in the art will recognize improvements and modifications to the embodiments of the present disclosure. All such improvements and modifications are considered within the scope of the concepts disclosed herein and the claims that follow.

What is claimed is:

1. An acoustic impedance inverter comprising:
a piezo-on-insulator (POI) layer provided on a substrate;
a pair of reflectors provided on the POI layer; and
a pair of interdigital transducers (IDTs) provided on the POI layer in between the pair of reflectors, the pair of IDTs are acoustically coupled to provide an impedance inversion and pass a radio frequency (RF) signal at a selected frequency.

2. The acoustic impedance inverter of claim 1, wherein each IDT in the pair of IDTs is coupled between a respective one of an input port and an output port, and a common port.

3. The acoustic impedance inverter of claim 2, wherein:
a first one of the pair of IDTs is coupled between the input port and the common port and configured to convert the RF signal into an acoustic wave; and
a second one of the pair of IDTs is coupled between the common port and the output port and configured to convert the acoustic wave back to the RF signal.

4. The acoustic impedance inverter of claim 2, wherein each of the input port, the output port, and the common port is coupled to a respective capacitor.

5. The acoustic impedance inverter of claim 1, further comprising a tuner circuit provided on the POI layer and in between the pair of IDTs, the tuner circuit is tuned by a direct-current (DC) voltage to change the selected frequency.

6. The acoustic impedance inverter of claim 5, wherein the tuner circuit comprises:
a silicon dioxide (SiO₂) layer provided on the POI layer;
a silicon (Si) layer provided on the SiO₂ layer; and
a pair of electrodes provided on the SiO₂ layer and on each side of the Si layer to form a pair of lateral sides of the Si layer, the pair of electrodes is configured to receive the DC voltage.

7. An acoustic filter circuit comprising:
an acoustic impedance inverter comprising:
a piezo-on-insulator (POI) layer provided on a substrate;
a pair of reflectors provided on the POI layer; and
a pair of interdigital transducers (IDTs) provided on the POI layer in between the pair of reflectors, the pair of IDTs are acoustically coupled to provide an impedance inversion and pass a radio frequency (RF) signal at a selected frequency; and
an acoustic filter coupled to the acoustic impedance inverter and configured to:
pass the RF signal to a load circuit at the selected frequency; and
block the RF signal from the load circuit outside the selected frequency.

8. The acoustic filter circuit of claim 7, wherein each IDT in the pair of IDTs is coupled between a respective one of an input port and an output port, and a common port.

9. The acoustic impedance inverter of claim 8, wherein:
a first one of the pair of IDTs is coupled between the input port and the common port and configured to convert the RF signal into an acoustic wave; and
a second one of the pair of IDTs is coupled between the common port and the output port and configured to convert the acoustic wave back to the RF signal.

10. The acoustic filter circuit of claim 8, wherein each of the input port, the output port, and the common port is coupled to a respective capacitor.

11. The acoustic filter circuit of claim 7, wherein the acoustic impedance inverter further comprises a tuner circuit provided on the POI layer and in between the pair of IDTs, the tuner circuit is tuned by a direct-current (DC) voltage to change the selected frequency.

12. The acoustic filter circuit of claim 11, wherein the tuner circuit comprises:
a silicon dioxide (SiO₂) layer provided on the POI layer;
a silicon (Si) layer provided on the SiO₂ layer; and
a pair of electrodes provided on the SiO₂ layer and on each side of the Si layer to form a pair of lateral sides of the Si layer, the pair of electrodes is configured to receive the DC voltage.

13. A wireless device comprising at least one acoustic filter circuit, the at least one acoustic filter circuit comprises:
an acoustic impedance inverter comprising:
a piezo-on-insulator (POI) layer provided on a substrate;
a pair of reflectors provided on the POI layer; and
a pair of interdigital transducers (IDTs) provided on the POI layer in between the pair of reflectors, the pair of IDTs are acoustically coupled to provide an impedance inversion and pass a radio frequency (RF) signal at a selected frequency; and
an acoustic filter coupled to the acoustic impedance inverter and configured to:
pass the RF signal to a load circuit at the selected frequency; and
block the RF signal from the load circuit outside the selected frequency.

14. The wireless device of claim 13, wherein each IDT in the pair of IDTs is coupled between a respective one of an input port and an output port, and a common port.

15. The acoustic impedance inverter of claim 14, wherein:
a first one of the pair of IDTs is coupled between the input port and the common port and configured to convert the RF signal into an acoustic wave; and
a second one of the pair of IDTs is coupled between the common port and the output port and configured to convert the acoustic wave back to the RF signal.

16. The wireless device of claim 14, wherein each of the input port, the output port, and the common port is coupled to a respective capacitor.

17. The wireless device of claim 14, wherein the acoustic impedance inverter further comprises a tuner circuit provided on the POI layer and in between the pair of IDTs, the tuner circuit is tuned by a direct-current (DC) voltage to change the selected frequency.

18. The wireless device of claim 17, wherein the tuner circuit comprises:
a silicon dioxide (SiO₂) layer provided on the POI layer;
a silicon (Si) layer provided on the SiO₂ layer; and
a pair of electrodes provided on the SiO₂ layer and on each side of the Si layer to form a pair of lateral sides of the Si layer, the pair of electrodes is configured to receive the DC voltage.

19. A method for implementing an acoustic impedance inverter comprising:
providing a piezo-on-insulator (POI) layer on a substrate;
providing a pair of reflectors on the POI layer;
providing a pair of interdigital transducers (IDTs) on the POI layer in between the pair of reflectors; and
acoustically coupling the pair of IDTs to provide an impedance inversion and pass a radio frequency (RF) signal at a selected frequency.

20. The method of claim 19, further comprising:
converting, via a first one of the pair of IDTs, the RF signal into an acoustic wave; and
converting, via a second one of the pair of IDTs, the acoustic wave back to the RF signal.
